(19) United States
(12) Patent Application Publication
(10) Pub. No.: US 2014/0168980 A1
(43) Pub. Date: Jun. 19, 2014

(54) ARRANGEMENT OF A HEAT SINK AND HEAT-GENERATING ELECTRONIC COMPONENTS HOUSED THEREON

(71) Applicant: DIEHL AEROSPACE GMBH, Uberlingen (DE)

(72) Inventors: Matthias HARTMANN, Feucht (DE); Uwe WOLFF, Forchheim (DE); Sebastian SICKER, Nurnberg (DE)

(73) Assignee: DIEHL AEROSPACE GMBH, Uberlingen (DE)

(21) Appl. No.: 14/104,115

(22) Filed: Dec. 12, 2013

(30) Foreign Application Priority Data
Dec. 14, 2012 (DE) 102012024459.2

(51) Int. Cl. H05K 7/20; F21V 29/00

(52) U.S. Cl. CPC H05K 7/2039; F21V 29/22
USPC 362/249.02; 361/704

(57) ABSTRACT

The invention concerns an arrangement of a heat sink and heat-generating electronic components housed thereon, in which the heat sink comprises a main part (1) and a moulding (2) of plastic with first fitting interfaces, in which the electronic components are arranged on the first side (7) of the main part (1) with thermal contact to said main part, and in which sections of a second side (8) of the main part (1) opposite the first side (7) are not insert moulded.

### BACKGROUND OF THE INVENTION

The invention is directed to an arrangement of a heat sink and heat-generating electronic components housed thereon. In particular, it relates to an LED light for use in a passenger aircraft.

### DISCUSSION OF THE PRIOR ART

According to the state of the art, arranging heat-generating electronic components on a heat sink produced from extrusion-moulded aluminium is known. Aluminium heat sinks have the effect of dissipating heat from electronic components. Furthermore, fitting interfaces are provided, giving the arrangement structural strength. Aluminium heat sinks embody a comparably high weight and are more expensive to produce.

### SUMMARY OF THE INVENTION

The task of the invention is to remove the disadvantages according to the state of the art. In particular, such an arrangement is to be declared embodying a low weight and which is economical to produce.

This task is solved by the characteristics of claims 1 and 14. Advantageous embodiments are produced from the characteristics of claims 2 to 13 and 15.

According to the invention, a heat sink is provided comprising a main part and a plastic moulding with first fitting interfaces. The electronic components are arranged on a first side of the main part with thermal contact with said main part. At least sections of a second side of the main part opposite the first side are not insert moulded. Together with the moulding, the main part forms a hybrid body.

By providing a moulding with first fitting interfaces, the main part can be designed without fitting interfaces. Therefore, the main part can be of smaller construction, thus saving weight. Furthermore, for example, chip-removal type machining can be avoided in the production of the main part. The production of the main part can be done more economically.

The main part may embody a thermal conductivity of more than 10 W/(m·K). Preferably, the main part may embody a thermal conductivity of more than 100 W/(m·K) and particularly preferably of more than 200 W/(m·K). Thus heat can be dissipated effectively from the electronic components. In particular, metals, ceramics and thermally-conductive plastics are considered as materials for the main part. The main part can be provided with a surface coating.

According to an advantageous embodiment, the main part comprises at least one metal part. The heat generated by the electronic components can be effectively dissipated by means of the metal part and the arrangement can simultaneously provide good structural strength.

The metal part may be a sheet, an extruded section or a die casting. According to an advantageous embodiment, the metal part is produced from aluminium. As a light metal, aluminium is particularly suitable for use in aviation.

The electronic components may be housed on a board, which is fitted on the first side. In particular, the electronic components may be light-emitting diodes. Thus, the arrangement in accordance with the invention assumes the dissipation of the heat generated by the light-emitting diodes when they are in operation.

The main part may embody two fitting interfaces. The first and second fitting interfaces may embody correspondingly arranged and formed perforations, so that fastenings may also extend through both perforations. By means of the fastenings, for example, a board can be fastened to the heat sink.

The first fitting interfaces may also comprise snap hooks. The snap hooks may be engageable in a counterpart located on the first side. The counterpart may be a lens holder or lens able to be arranged on the board.

The first fitting interfaces on the moulding may also enable a fastening of the arrangement to a frame structure.

The moulding may encompass two opposite edges of the advantageously flat-shaped main part. For example, the moulding may be produced in an injection moulding process by using a thermoplastic polymer.

A liquid crystal polymer may be used as the polymer. Liquid crystal polymers (LCP) are characterised by a high tensile strength, a high modulus of elasticity and a high melting point.

The thermal expansion coefficients of the main part and the moulding are advantageously adapted to each other. This avoids stresses due to thermal effects or a crack between the moulding and main part.

According to the scope of the invention, an LED light is also proposed, in which on the first side of the heat sink described above, a board equipped with light-emitting diodes is fitted. With the proposed LED light, the heat generated can be effectively dissipated, even at high illumination intensities. The proposed LED light is also characterised by a small construction size, a low weight and economical production.

In accordance with an advantageous embodiment, with the proposed LED light, the board can be fastened to the heat sink with self-tapping screws. In this case it is not necessary to tap a thread beforehand in a separate process.

### BRIEF DESCRIPTION OF THE DRAWINGS

In the following, embodiments of the invention are explained in more detail using the drawings, in which:

FIG. 1 shows a perspective view of a first heat sink,

FIG. 2 shows a perspective view of the heat sink according to FIG. 1 in an exploded view,

FIG. 3 shows a perspective view of a second heat sink,

FIG. 4 shows a perspective view of the heat sink according to FIG. 3 in an exploded view and

FIG. 5 shows a perspective view of an LED light.

### DETAILED DESCRIPTION OF THE INVENTION

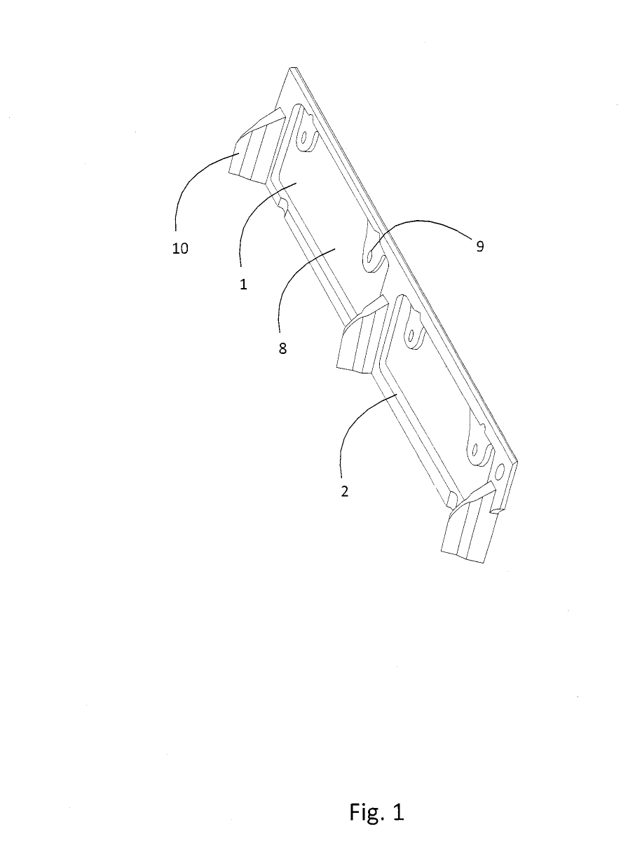

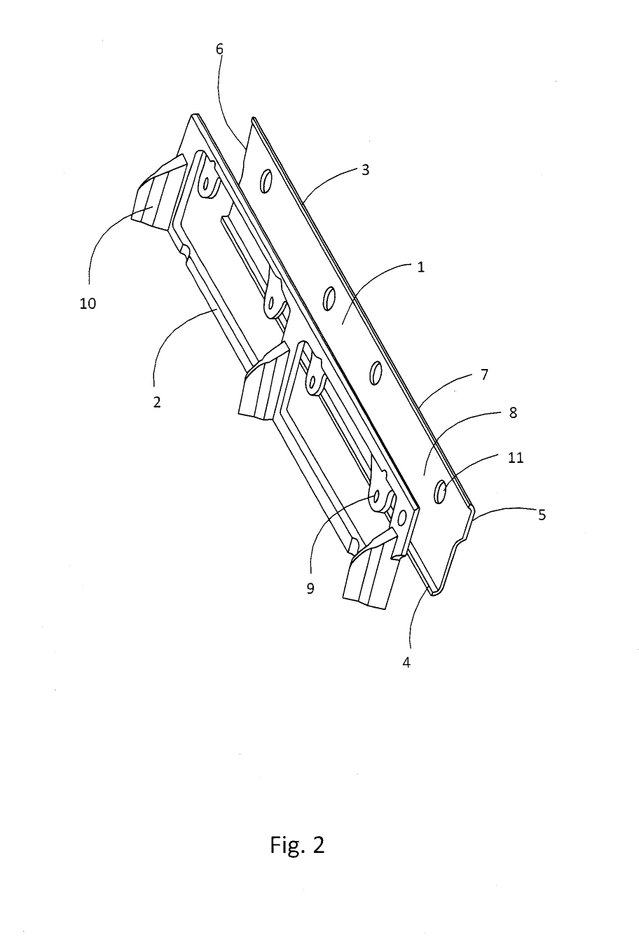

The first heat sink shown in FIG. 1 and FIG. 2 comprises a main part 1 and a moulding 2. The main part 1 consists of an essentially rectangular metal plate made of injection-moulded aluminium with two opposite long edges 3, 4 and two opposite short edges 5, 6 and a first side 7 and a second side 8. The moulding 2 is produced by moulding around the main part 1 with a thermoplastic polymer in an injection moulding process. The long edges 3, 4 and short edges 5, 6 of main part 1 are completely surrounded by the moulding. The long edges 3, 4 embody a bend in the direction of the second side 8. The first side 7 of the main part 1 is free of the moulding, apart from its edge area. Sections of the second side 8 of the main part 1 are covered by the first fitting interfaces formed on the moulding.

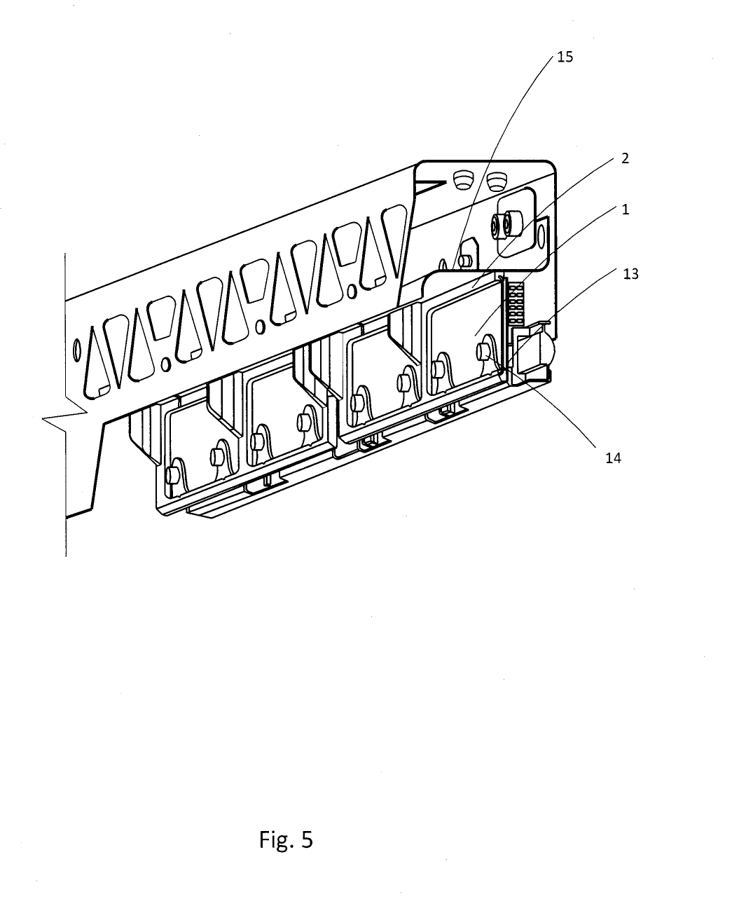

The first fitting interfaces are shown here as rings embodying the first perforations 9 and as ribs 10. Corresponding to the first perforations 9, the main part 1 embodies second fitting interfaces formed as second perforations 11. The first 9 and second perforations 11 are provided in corresponding positions on the moulding 2 and on the main part 1, in such a way that the fastenings 14 shown in FIG. 5 can extend through the first 9 and second perforations 11.

The ribs 10 of the moulding 2 protrude somewhat vertically from the second side 8 of the main part 1. The ribs 10 embody blind holes (not shown here). Further fastenings (not shown) for fastening the first heat sink may engage into the blind holes to a frame structure not shown in FIG. 1 and FIG. 2.

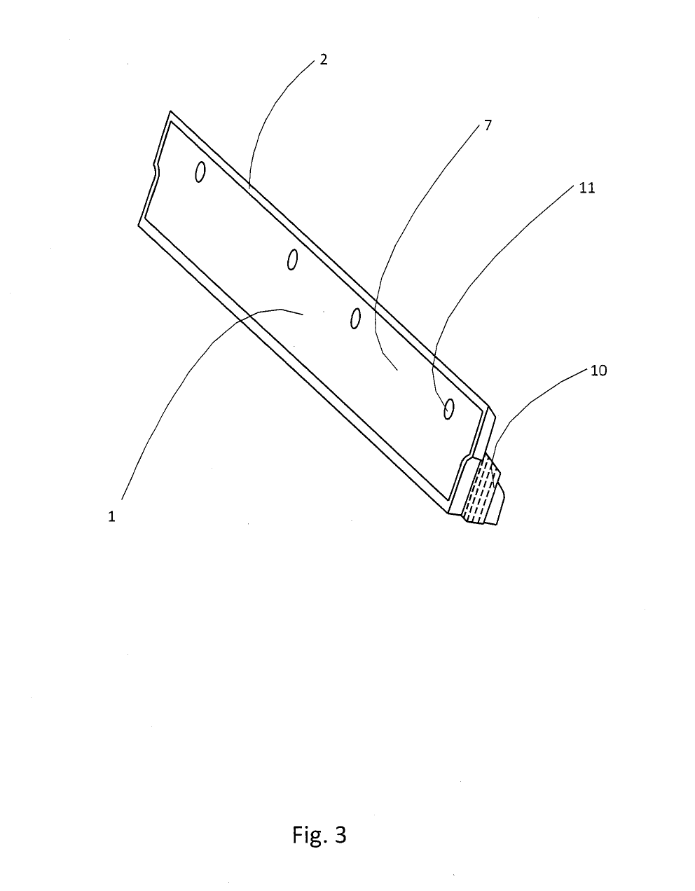

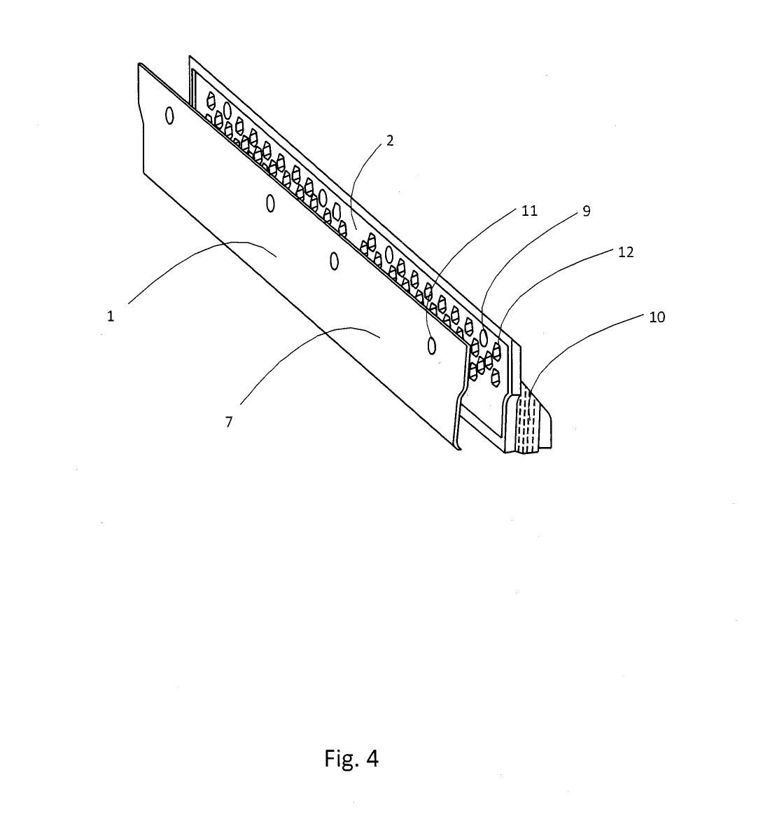

The second heat sink shown in FIG. 3 and FIG. 4 corresponds to the first heat sink with the difference that in the second heat sink, the moulding 2 extends over the second side 8 of the main part 1. The moulding 2 embodies a number of further perforations 12 here. The further perforations 12 enable a heat dissipation from the main part 1.

FIG. 5 shows a perspective view of an LED light. The LED light comprises the first heat sinks with main part 1 and moulding 2. On the first side 7 of the main part 1, a board 13 equipped with light-emitting diodes is fitted by means of fastenings 14, which board extends through the first 9 and second perforations 11. The fastenings 14 are, for example, self-tapping screws.

The arrangement in accordance with the invention is fastened to a frame structure 15 by means of a further unnoticeable fastening in FIG. 5. The further fastenings engage into the blind holes provided in the ribs 10. The further fastenings are, for example, self-tapping screws.

In the following, the function of the arrangement in accordance with the invention is explained in more detail. Main part 1 is used to dissipate the heat generated by the light-emitting diodes in operation and provides the structural strength of the arrangement. The moulding 2 is used to provide first and second fitting interfaces.

By providing the moulding 2, fewer functions are provided by the main part 1. This enables the main part 1 to be constructed more simply, thus saving weight. Production is more economical.

### LIST OF REFERENCE SYMBOLS

1 Main part
2 Moulding
3 First long edge
4 Second long edge
5 First short edge
6 Second short edge
7 First side
8 Second side
9 First perforations
10 Ribs
11 Second perforations
12 Other perforations
13 Board
14 Fastenings
15 Frame structure

What is claimed is:

1. An arrangement of a heat sink and heat-generating electronic components housed thereon, in which the heat sink comprises a main part and a moulding of plastic with first fitting interfaces, wherein the electronic components are arranged on the first side of the main part with thermal contact to said main part, and in which sections of a second side of the main part opposite the first side are not insert moulded.

2. The arrangement according to claim 1, wherein the main part embodies a thermal conductivity of more than 10 W/(m·K).

3. The arrangement according to claim 1, wherein the main part embodies a thermal conductivity of more than 100 W/(m·K).

4. The arrangement according to claim 1, wherein the main part embodies a thermal conductivity of more than 200 W/(m·K).

5. The arrangement according to claim 1, wherein the main part comprises at least one metal part.

6. The arrangement according to claim 3, wherein the metal part is a sheet, an extruded section or a die casting.

7. The arrangement according to claim 3, wherein the metal part is produced from aluminium.

8. The arrangement according to claim 1, wherein the electronic components are housed on a board, which is fitted on the first side.

9. The arrangement according to claim 1, wherein the electronic components are light-emitting diodes.

10. The arrangement according to claims 1, wherein the main part embodies two fitting interfaces.

11. The arrangement according to claim 8, wherein the first and second fitting interfaces embody correspondingly arranged and formed perforations, so that the fastenings can extend through the first and second perforations.

12. The arrangement according to claim 1, wherein the first fitting interfaces comprise snap hooks.

13. The arrangement according to claim 1, wherein the moulding encompasses two opposite edges of the main part.

14. The arrangement according to claim 1, wherein the moulding comprises a thermoplastic polymer.

15. The arrangement according to claim 14, wherein said thermoplastic polymer is a liquid crystal polymer.

16. The arrangement according to claim 1, wherein the thermal expansion coefficients of the main part and the moulding are adapted to each other.

17. A LED light comprising the arrangement of a heat sink according to claim 1, wherein the first side of the heat sink is fitted a board equipped with light-emitting diodes.

18. The LED light according to claim 14, in which the board is fastened to the heat sink with self-tapping screws.
